(19) United States
(12) Patent Application Publication
(10) Pub. No.: US 2012/0270359 A1
(43) Pub. Date: Oct. 25, 2012

(54) METHOD OF FORMING P-N JUNCTION IN SOLAR CELL SUBSTRATE

(75) Inventors: PRABHAT KUMAR, Fremont, CA (US); Jason Dominguez, Albuquerque, NM (US); David Tanner, San Jose, CA (US)

(73) Assignee: APPLIED MATERIALS, INC., Santa Clara, CA (US)

(21) Appl. No.: 13/406,102

(22) Filed: Feb. 27, 2012

Related U.S. Application Data
(60) Provisional application No. 61/477,928, filed on Apr. 21, 2011.

(51) Int. Cl. H01L 31/0236; H01L 31/02

(52) U.S. Cl. 438/71; 438/57; 257/E31.11; 257/E31.13

(57) ABSTRACT

Embodiments of the present invention relate to a single step diffusion process used in selective emitter solar cell fabrication. In one embodiment, a dopant paste is selectively applied on a front surface of a substrate having opposite conductivity type from the dopant paste. The substrate is then exposed to a dopant containing vapor to deposit a doping layer having opposite conductivity type from the substrate on the front surface of the substrate. While the substrate is exposed to the dopant containing vapor, a portion of the dopant paste also contribute to deposition of the doping layer via gas phase transport of doping atoms from the dopant paste. The substrate is then heated in an atmosphere comprising oxygen and/or nitrogen to a temperature sufficient to cause the dopant atoms in the dopant paste and the doping layer to diffuse into the substrate, forming heavily and lightly doped emitter regions.

### CROSS-REFERENCE TO RELATED APPLICATIONS

This application claims benefit of U.S. provisional patent application Ser. No. 61/477,928, filed Apr. 21, 2011, which is herein incorporated by reference.

### BACKGROUND OF THE INVENTION

1. Field of the Invention

Embodiments of the present invention generally relate to a system and process for forming selective emitter solar cells.

2. Description of the Related Art

Solar cells are photovoltaic (PV) devices that convert sunlight into electrical power. A typical solar cell includes a substrate, or wafer, that has one or more p-n junctions formed therein. Each p-n junction has a p-type region and an n-type region. When the p-n junction of a solar cell is exposed to sunlight (consisting of energy from photons), the sunlight is converted to electricity through the PV effect. Solar cells generate a specific amount of electric power and are tiled into modules sized to deliver a desired amount of system power.

FIG. 1A schematically depicts an isometric view of a selective emitter solar cell 10. FIG. 1B depicts a cross-sectional side view of the solar cell 10 shown in FIG. 1A taken along line B-B. The solar cell 10 is typically fabricated on a silicon substrate 11, which includes a p-type base region 21, an n-type emitter region 22, and a p-n junction region 23 disposed therebetween. The n-type emitter region 22 is formed by doping the substrate 11 with certain types of elements which can donate the carriers in order to increase the number of negative charge carriers, i.e., electrons. Similarly, the p-type base region 21 may be formed by the addition of trivalent dopant atoms to the crystal lattice, resulting in a missing electron from one of the four covalent bonds normal for the silicon lattice. The dopant atom accepts an electron, causing the loss of half of one bond from the neighboring atom, resulting in the formation of a “hole.”

When the solar cell 10 is exposed to light, energy from incident photons generates electron-hole pairs on both sides of the p-n junction region 23. Electrons and holes diffuse in opposite directions creating a negative charge in the n-type emitter region 22 and a corresponding positive charge in the p-type base region 21. Current flows when an electrical circuit is made between the n-type emitter region 22 and the p-type base regions 21 as the p-n junction is exposed to certain wavelengths of light. The electrical current generated flows through conductive contacts 14 (known as contact fingers), disposed on the front side 18, i.e., the light receiving side, and a back contact 25 on the back side 19 of the solar cell 10. The conductive contacts 14 supply the current to a larger bus bar 15 (FIG. 1A). The solar cell 10 is generally covered with a thin layer of dielectric material to act as an anti-reflection coating 16 to minimize light reflection from a top surface 22A of the solar cell 10.

To enhance the contact with the solar cell 10, the conductive contacts 14 are positioned on heavily doped regions 17 formed within the substrate surface to enable low resistance contact with the n-type emitter region 22. Due to their electrical properties, the heavily doped regions 17 tend to block or minimize the amount of light that can pass therethrough. Therefore, it is desirable to minimize the size of the heavily doped regions 17, while ensuring that these regions are large enough to reliably provide adequate conduction between the conductive contacts 14 and the n-type emitter region 22.

The n-type emitter region 22 is typically formed on the substrate surface using a two-step dopant diffusion process to create areas of heavier and lighter doping. Generally, one or more doping materials are selectively applied and dried on a front surface of the substrate. The substrate is then subjected to a first diffusion step at high temperature to cause the doping materials to drive-in or diffuse into the front surface of the substrate, forming heavily doped regions 17. Thereafter, the front surface of the substrate is exposed to a dopant containing vapor or gas and the dopant atom is driven into the front surface at lower temperature in a second diffusion step to form a lightly doped region 24. However, such two-step dopant diffusion processes require a high thermal budget in the manufacturing process and result in increased processing times and reduced substrate throughput.

Therefore, there is a need for improved processes for forming selective emitter solar cells.

### SUMMARY OF THE INVENTION

Embodiments of the present invention are directed to improved process for making solar cells. In one embodiment, a method for forming a solar cell includes selectively applying a dopant material layer onto a surface of a substrate, the dopant material layer having opposite conductivity type from the substrate, ramping up the temperature of the substrate in an oxygen-rich environment to diffuse the dopant material layer into the surface of the substrate, exposing the substrate to a dopant containing vapor to deposit a doping layer on the surface of the substrate, the doping layer having opposite conductivity type from the substrate, and heating the substrate to a temperature sufficient to cause dopant atoms in the dopant material and dopant atoms in the dopant layer to diffuse into the textured surface a desired distance.

In another embodiment, a method for forming a solar cell includes texturing a surface of a substrate, selectively applying a dopant material layer onto the textured surface of the substrate, the dopant material layer having opposite conductivity type from the substrate, exposing the substrate to a dopant containing vapor to deposit a doping layer on the textured surface, the doping layer having opposite conductivity type from the substrate, and heating the substrate to a temperature sufficient to cause dopant atoms in the dopant material and dopant atoms in the dopant layer to diffuse into the textured surface a desired distance.

In yet another embodiment, a method for forming a solar cell includes texturing a surface of a substrate, selectively applying a dopant material layer onto the textured surface of the substrate, the dopant material layer having opposite conductivity type from the substrate, exposing the substrate to a dopant containing vapor to deposit a doping layer on the textured surface, the doping layer having opposite conductivity type from the substrate, and heating the substrate to a temperature sufficient to diffuse dopant atoms in the dopant material into the substrate to create a pattern of heavily doped regions and dopant atoms in the dopant layer into the textured surface to create lightly doped field regions, wherein the lightly doped regions are formed in between the heavily doped regions.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is an isometric view of a selective emitter solar cell.

FIG. 1B is a cross-sectional view of the solar cell shown in FIG. 1A taken along line B-B.

FIG. 2 is a schematic, plan view of an exemplary in-line processing system used to form a selective emitter solar cell using a processing sequence according to at least one embodiment of the invention.

FIGS. 3A-3H are schematic, cross-sectional views of a solar cell substrate during different stages using a processing sequence according to at least one embodiment of the invention.

FIG. 4 is a block diagram of a processing sequence used to form a selective emitter solar cell shown in FIGS. 3A-3H using the exemplary in-line system of FIG. 2.

Appendix contains conventional process and various illustrations of different embodiments of the process according to embodiments described herein.

### DETAILED DESCRIPTION

Embodiments of the present invention are directed to improved processes for making solar cells. Particularly, embodiments of the invention provide a single step diffusion process to be used in selective emitter solar cell fabrication at lower temperatures of about 850° C. or less using dopant paste (which is generally tough to diffuse at low temperature). In one embodiment, a front surface of a p-type substrate is textured and an n-type dopant paste is selectively applied and optionally dried on the front surface of the substrate. The substrate is then exposed to a dopant containing vapor, e.g., phosphorus oxychloride (POCl₃), to deposit a doping layer on the front surface of the substrate. While the substrate is exposed to POCl₃ vapor, a portion of the dopant paste may also contribute to deposition of the doping layer via gas phase transport of phosphorus from the dopant paste, thereby improving the doping efficiency of P atoms near the surface of the substrate. The substrate is then heated and annealed in an atmosphere comprising nitrogen and/or oxygen to a temperature that is sufficient to concurrently activate and cause the dopant atoms in the dopant paste and the doping layer to diffuse into the substrate a desired distance, forming heavily doped and lightly doped emitter regions.

In various embodiments, the heavily doped regions have a low sheet resistance which provides a highly conductive path between the emitter region and the subsequently formed conductive contacts, whereas the lightly doped region has higher sheet resistance which reduces the recombination of carriers and absorbs minimal light so that an increased amount of light is transmitted to the p-n junction for conversion into electrical current. The inventive single step diffusion process allows the manufacturing of solar cells with reduced thermal budget and increased substrate throughput. In addition, the doping efficiency near the front surface of the solar cell is significantly improved compared to conventional two-step diffusion process. The inventive diffusion process is well suited for multicrystalline, upgraded metallurgical silicon, monocast silicon where the impurity levels are higher compared to mono-crystalline CZ silicon. At higher temperature (e.g., greater than 850° C.), the impurity in silicon wafer degrades the lifetime of minority carrier resulting in mediocre solar cell performance.

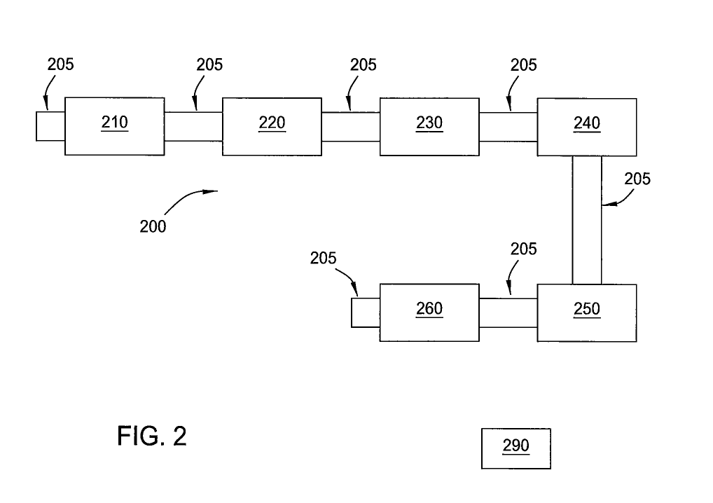

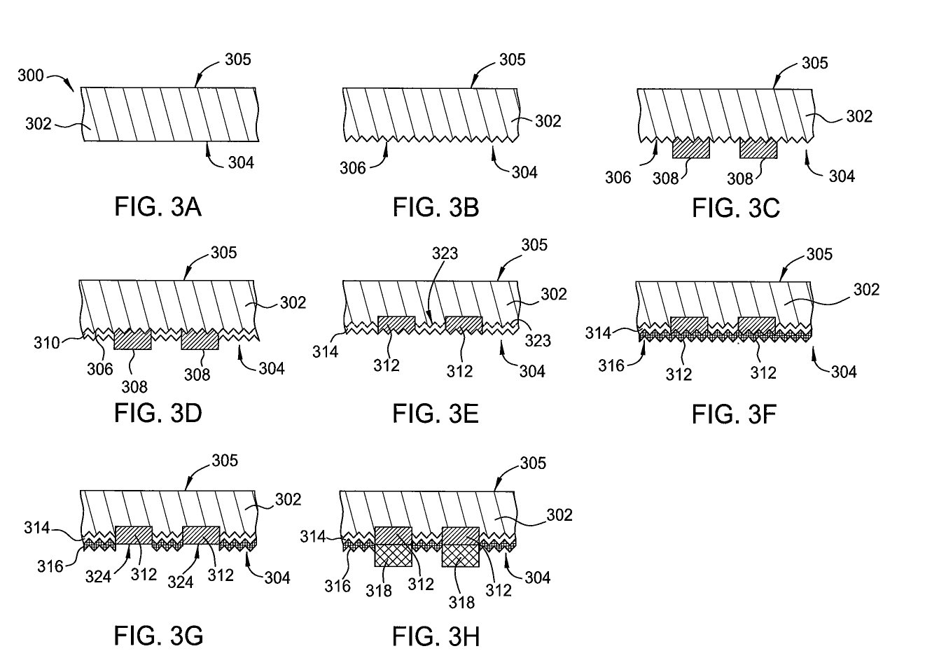

FIG. 2 is a schematic, plan view of an exemplary in-line processing system used to form a selective emitter solar cell using a processing sequence according to at least one embodiment of the invention. The in-line processing system 200 includes a first cleaning chamber 210, a dopant application chamber 220, a drying chamber 230, a thermal processing chamber 240, a second cleaning chamber 250, a deposition chamber 260, and a chamber controller 290. In the in-line processing system 200, a substrate, such as the substrate 302 shown in FIGS. 3A-3H, is supported and transferred through the in-line processing system 200 on one or more conveyors 205. The conveyors 205 may include a plurality of conveyor belts driven by actuators, such as one or more motors. It should be noted that the in-line processing system illustrated in FIG. 2 is merely an exemplary system configuration used to manufacture the selective emitter solar cell of the invention. One or more chambers can be added, deleted and/or reordered depending upon the process scheme or application.

The chamber controller 290 is a general use computer that is used to control one or more components/chambers found in the in-line processing system 200. The chamber controller 290 is generally designed to facilitate the control and automation of the overall system and may include a central processing unit (CPU) (not shown), memory (not shown), and support circuits (not shown). The CPU may be one of any form of computer processors that are used in industrial settings for controlling various chamber processes and hardware (e.g., conveyors, motors, fluid delivery hardware, laser hardware, thermal processing hardware, cleaning hardware) and monitor the system and chamber processes (e.g., substrate position, process time). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, and the like. A program (or computer instructions) readable by the chamber controller 290 determines which tasks are performable on the substrate 302. The program may be software readable by the chamber controller 290, which includes code to generate and store at least substrate positional information, the sequence of movement of the various controlled components, cleaning processing information, thermal processing information, and any combination thereof.

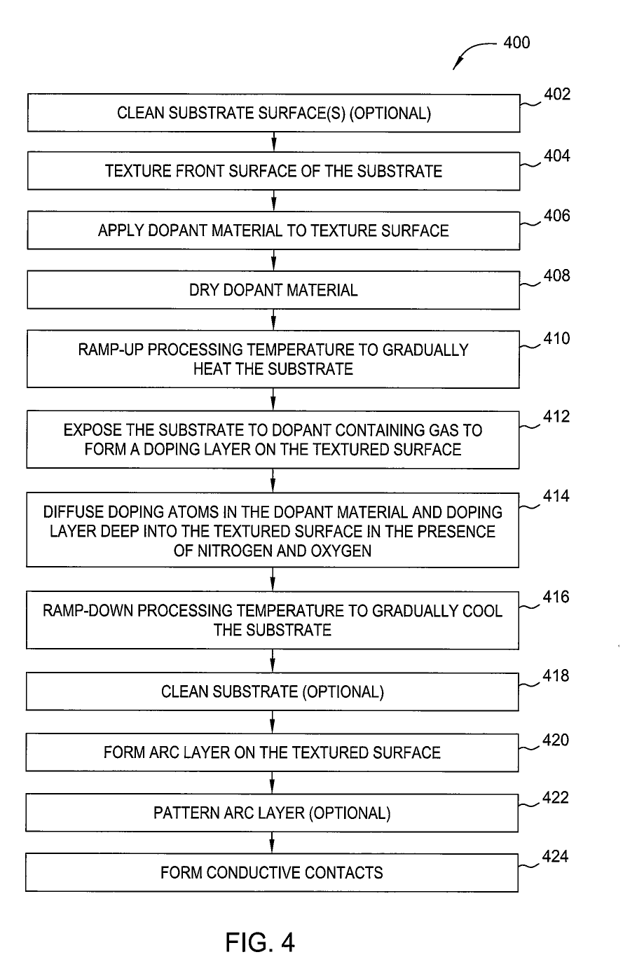

FIGS. 3A-3H are schematic, cross-sectional views of a solar cell substrate 300 during different stages using a processing sequence 400 according to at least one embodiment of the invention. FIG. 4 is a block diagram of the processing sequence used to form the solar cell shown in FIGS. 3A-3H using the exemplary in-line system of FIG. 2. The sequence shown in FIG. 4 corresponds to the stages depicted in FIGS. 3A-3H. While only front side structures are shown in FIGS. 3A-3H, it is contemplated that one or more layers of metalized backside contact structure may be formed on the backside of the solar cell substrate at any desired stage.

In various embodiments of this invention, the substrate can be formed from single crystalline silicon (mono-Si) or multicrystalline silicon (mc-Si). The crystalline silicon substrate may be an electronic grade silicon substrate or a low lifetime, defect-rich silicon substrate, for example, an upgraded metallurgical grade (UMG) crystalline silicon substrate. The upgraded metallurgical grade (UMG) silicon is a relatively clean polysilicon raw material having a low concentration of heavy metals and other harmful impurities, preferably in the parts per million range, but which may contain a high concentration of boron or phosphorus, depending on the source. In certain applications, the substrate can be a back-contact silicon substrate prepared by emitter wrap through (EWT), metallization wrap around (MWA), or metallization wrap through (MWT) approaches. Generally, MWA and MWT have metal current collection grids on the front surface. These grids are, respectively, wrapped around the edge or through holes to the back surface in order to make a back-contact cell. As for EWT cells, there is no metal coverage on the front side of the cell. The EWT cell wraps the current-collection junction (“emitter”) from the front surface to the rear surface through doped conductive channels in the silicon wafer. Such conductive channels can be produced by, for example, drilling holes in the silicon substrate with a laser and subsequently forming the emitter inside the holes at the same time as forming the emitter on front and rear surfaces. Further discussion regarding EWT cells may be found in U.S. Pat. No. 5,468,652, entitled “Method Of Making A Back Contacted Solar Cell”.

At step 402 shown in FIG. 4, a substrate 302 is provided in a first cleaning chamber 210 (FIG. 2) and an optional clean process is performed to clean surfaces of a substrate 302 to remove any undesirable materials. The substrate 302 has a front surface 304 and a back surface 305 that is generally opposite to the front surface 304 and on the opposite side of the substrate 302, as shown in FIG. 3A. The substrate 302 may be formed from single crystalline silicon (mono-Si) or multicrystalline silicon (mc-Si). In one example, the substrate 302 is a p-type crystalline silicon (c-Si) substrate. While FIGS. 3A-3H and relevant discussion thereof primarily discuss the use of a p-type c-Si substrate, this configuration is not intended to be limiting as to the scope of the invention, since an n-type c-Si substrate may also be used without deviating from the basic scope of the embodiments of the invention described herein. The doping layers or emitters formed over the substrate will vary based on the type of substrate that is used, as will be discussed below.

During the optional clean process in step 402, the substrates 302 may be cleaned using a plasma cleaning process or a wet cleaning process in which they are sprayed with cleaning solution. The cleaning solution may be any conventional cleaning solution, such as HF-last type cleaning solution, ozonated water cleaning solution, hydrofluoric acid (HF) and hydrogen peroxide (H₂O₂) solution, or other suitable cleaning solution. The cleaning process may be performed on the substrate 302 between about 5 seconds and about 600 seconds, such as about 120 seconds.

At step 404 shown in FIG. 4, a texture etching process is performed on a surface 304 of the substrate 302 in the first cleaning chamber 210 (FIG. 2) to form a textured surface 306, as shown in FIG. 3B. The textured surface 306 is typically the front side of a solar cell substrate that is adapted to receive sunlight after the solar cell has been formed. The textured surface 306 is formed to enhance light trapping in the solar cells to improve conversion efficiency. In one example, the substrate is etched in an etching solution comprising between about 2.7% by volume of potassium hydroxide (KOH) and about 4500 ppm of 300 MW PEG that is maintained at a temperature of about 79-80° C. for about 30 minutes. In one embodiment, the etching solution for etching a silicon substrate may be an aqueous potassium hydroxide (KOH), sodium hydroxide (NaOH), aqueous ammonia (NH₄OH), tetramethylammonium hydroxide (TMAH; or (CH₃)₄NOH), or other similar basic solution. The etching solution will generally anisotropically etch the substrate 302, forming pyramids on the textured surface 306 of the substrate 302. Examples of an exemplary cleaning process (step 402) or texture etching process (step 404) can be found, for example, in the U.S. patent application Ser. No. 12/383,350, entitled “SURFACE CLEANING AND TEXTURING PROCESS FOR CRYSTALLINE SOLAR CELLS”, filed Mar. 23, 2009.

At step 406 shown in FIG. 4, a dopant material 308 is applied to the textured surface 306 of the substrate 302 in a dopant application chamber 220 (FIG. 2), as shown in FIG. 3C. While FIG. 3C depicts the dopant material 308 applied to only the textured surface 306 of the substrate 302, in some embodiments the dopant material 308 may be applied to both sides of the substrate 302. In cases where the substrate 302 is a p-type substrate, the dopant material 308 is an n-type dopant material. Typical n-type dopants used in silicon solar cell manufacturing are elements such as phosphorus (P), arsenic (As), or antimony (Sb). The dopant material 308 may be phosphorus oxychloride (POCl₃). Other examples may include, but are not limited to polyphosphoric acid, phosphosilicate glass precursors, phosphoric acid (H₃PO₄), phosphorus acid (H₃PO₃), hypophosphorous acid (H₃PO₂), and/or various ammonium salts thereof. In cases where the substrate 302 is an n-type substrate, the dopant material 308 may be a p-type dopant material, such as boric acid (H₃PO₃). In either case, the dopant material 308 may be deposited or printed in a desired pattern by the use of screen printing, ink jet printing, spray deposition, rubber stamping, laser diffusion or other similar process. The dopant material 308 may initially be a liquid, paste, or gel that is used to form the heavily doped regions 312 (FIG. 3E) in the substrate 302 in a subsequent processing step.

At step 408 shown in FIG. 4, the substrate 302 may be optionally processed in a drying chamber 230 (FIG. 2) to dry the dopant material 308 into a uniform and more solid state. The substrate 302 may be processed at a desired temperature between about 50° C. and about 500° C. The temperature of the drying chamber 230 is controlled to be high enough that the dopant material 308 is dried into at least a “tacky” state, densified, and/or formed a bond with the front surface 304 of the substrate 302, but low enough that the dopant atoms in the dopant material are not diffused into the substrate 302, as shown in FIG. 3C.

At step 410 shown in FIG. 4, the substrate 302 is gradually heated to a temperature greater than about 800° C. in a thermal processing chamber 240 (FIG. 2). The temperature of the thermal processing chamber 240 may be ramped up from a stabilization temperature of about 700° C. to about 850° C. at ramp-up rate between about 25° C./sec. and about 500° C./sec. In one example, the substrate 302 is gradually heated to a temperature range between about 750° C. and about 1000° C., for example between about 800° C. and about 850° C., in the presence of oxygen (O₂), or in the presence of oxygen (O₂) and nitrogen (N₂) for between about 1 minute and about 120 minutes, for example, about 15 minutes and about 30 minutes, depending upon the targeted sheet resistance value. Other gas such as hydrogen (H₂), air, or combinations thereof is also contemplated during the temperature ramp-up period.

While not clearly shown, the thermal processing of the substrate 302 during this temperature ramp-up period may also cause the doping atoms of the dopant material 308 to slightly or partially diffuse into the textured surface 306 of the substrate 302, thereby improving the doping efficiency of P atoms near the front surface 304 of the substrate 302. In one example, the substrate 302 is gradually heated in an oxygen (O₂) rich environment in a rapid thermal annealing (RTA) chamber to a temperature range of about 800° C. to about 850° C. Alternatively, the substrate 302 may be gradually heated in a nitrogen (N₂) rich environment. One exemplary in-line processing system that may be modified to accomplish the thermal processing step is the ATON system manufactured by Applied Materials, Inc. of Santa Clara, Calif.

At step 412 shown in FIG. 4, while the substrate 302 is thermally processed in the thermal processing chamber 240 (FIG. 2), a desirable dopant containing gas, e.g., phosphorus oxychloride (POCl₃), may be supplied into the chamber 240 such that the front surface 304 of the substrate 302 is exposed to the POCl₃vapor, thereby depositing a doping layer 310 containing POCl₃ on the textured surface 306 of the substrate 302, as shown in FIG. 3D. The doping layer 310 generally is a thin layer formed in between the dopant materials 308. In one example, the doping layer 310 may be at a layer thickness from about 10 Å to about 90,000 Å, for example, 30,000 Å, which may vary depending upon the deposition time. While not shown, a portion of the doping layer 310 may also deposit on and in between the dopant materials 308. It is contemplated that while the dopant material 308 and the doping layer 310 are shown being deposited at different stages, the doping layer 310 may be formed during formation of the dopant material 308. For example, the dopant material 308 may be deposited or printed in a desired pattern on the textured surface 306 of the substrate 302 while exposing the substrate 302 to the desirable dopant containing gas, such as a POCl₃ vapor, thereby forming a portion of the doping layer 310 on and/or in between the dopant materials 308 as shown in FIG. 3D.

The step 412 may be performed in the presence of nitrogen (N₂) and/or oxygen (O₂), and may optionally include a carrier gas such as hydrogen, helium, argon, or other suitable gas. If desired, an optional stabilization step maintaining the temperature of the thermal processing chamber 240 at about 850° C. may be performed for about 1-35 minutes prior to deposition of the doping layer 310. In cases where an n-type solar cell substrate is adapted, the front surface 304 of the substrate 302 may be exposed to a vapor, such as polyphosphoric acid, phosphosilicate glass precursors, phosphoric acid (H₃PO₄), phosphorus acid H₃PO₃), hypophosphorous acid (H₃PO₂), and/or various ammonium salts thereof, to deposit a doping layer on the textured surface 306.

During deposition of the doping layer 310, portions of the dopant material 308 are also vaporized to lightly dope the exposed region (i.e., surface area other than the dopant materials 308) of the substrate 302 to form a portion of the doping layer 310. That is, while the substrate 302 is exposed to the dopant containing vapor, a portion of the dopant material 308 may also contribute to deposition of the doping layer 310 via gas phase transport of doping atoms from the dopant material 308. Therefore, the doping efficiency of doping atoms near the surface of the substrate 302 is further improved. In certain examples of step 412, the doping layer 310 may be formed solely by gas phase transport of doping atoms resulted from the dopant material 308, without having the substrate 302 exposed to the dopant containing gas. While not shown, it is contemplated that some portions of the dopant material 308 may also deposit on the backside of the substrate 302 during thermal processing of the substrate 302.

At step 414 shown in FIG. 4, the supply of the dopant containing gas, for example, POCl₃, is terminated and a single step diffusion process is performed in the thermal processing chamber 240 to co-diffuse the doping atoms in the dopant material 308 and the doping atoms in the doping layer 310 deep into the front surface 304 of the substrate 302, thereby forming heavily doped regions 312 and lightly doped regions 314, as shown in FIG. 3E. The substrate 302 is typically annealed by delivering heat energy to the substrate 302 at a desired temperature, for example, about 850° C. or less, for a desired period of time that is sufficient to concurrently activate and cause the dopant atoms (e.g., phosphorous) in the dopant material 308 and doping layer 310 to diffuse into the substrate 302 a desired distance, depending upon the given heating energy. Annealing at lower temperature range, such as between about 800° C. and about 850° C., for example, about 825° C. and about 835° C., is desirable in certain applications since it reduces the thermal budget of the manufacturing process. The inventive single step diffusion process with reduced thermal budget is therefore not only beneficial to monocrystalline silicon substrates, but also compatible for defect-rich substrates, e.g., multicrystalline (polycrystalline) and upgraded metallurgical grade (UMG) silicon substrates, which is less expensive to manufacture than high purity polysilicon, thereby lowering the cost of making solar cells.

The dotted lines in FIG. 3E shows the status of the substrate 302 after the dopant material 308 and doping layer 310 have been diffused into the front surface 304 of the substrate 302. The resulting structure provides an n-type emitter region having a profile of lightly doped regions 314 formed in between heavily doped regions 312 on the front surface 304 of the substrate 302. Upon annealing, the lightly doped region 314 may be at a layer thickness from about 10 Å to about 90,000 Å, for example, 30,000 Å, while the heavily doped regions 312 may be at a layer thickness from about 10 Å to about 30,000 Å, or thicker as desired for the depth of the emitter in the substrate. In one example, the heavily doped regions 312 include between about 5% and about 85% of the front surface area of the substrate 302. After performing the processes in step 414, the heavily doped regions 312 may have a doping level greater than or equal to about 1×10¹⁹ atoms/cm³ and the lightly doped region 314 may have a doping level less than or equal to about 1×10¹⁸ atoms/cm³. While not discussed here, it is contemplated that the doping level of the heavily or lightly doped region may be controlled by increasing or decreasing the concentration of the dopant containing environment.

The single step diffusion process in step 414 may be performed in the presence of nitrogen and oxygen atmosphere at about 850° C. for about 30 minutes to about 120 minutes. Alternatively, the diffusion may be performed in the presence of nitrogen, oxygen, and phosphorus oxychloride (POCl₃). In certain applications, it may be desired to perform the single step diffusion process in a nitrogen-rich or pure nitrogen atmosphere at about 850° C. for about 1-60 minutes, followed by an oxygen-rich or pure oxygen atmosphere at about 850° C. for about 1-60 minutes. If desired, this single step diffusion process can be performed in a nitrogen-rich or pure nitrogen atmosphere throughout the diffusion process.

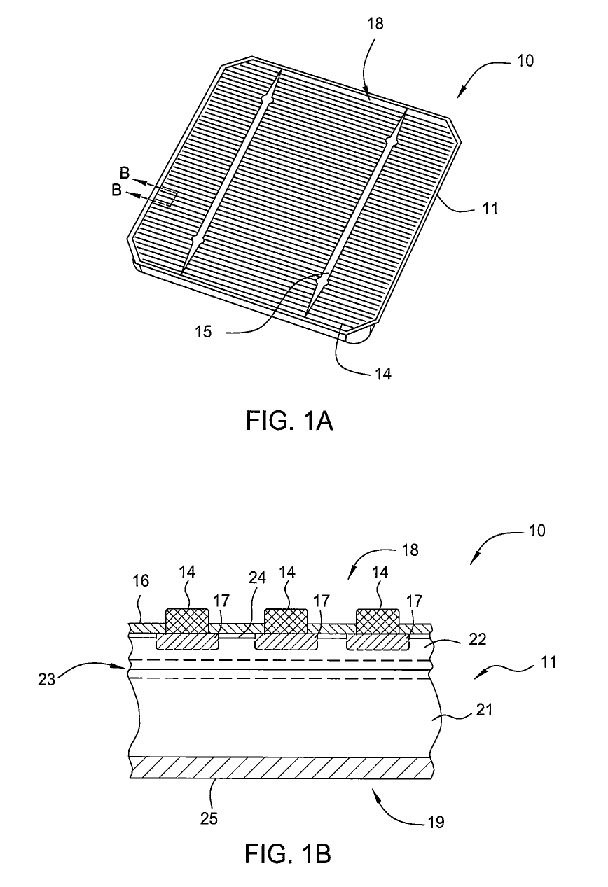

Upon completion of the diffusion in step 414, the heavily doped regions 312 of the substrate 302 generally have a sheet resistance (Rs) of less than 80 Ω/□, such as between about 20 Ω/□ and about 70 Ω/□, for example, between about 55 Ω/□ and about 60 Ω/□, while the lightly doped regions 314 (i.e., field area other than heavily doped regions 312) generally have a sheet resistance (Rs) of greater than about 60 Ω/□, such as between about 80 Ω/□ and about 120 Ω/□. The single step diffusion process enables low and high sheet emitter resistance provided on the front surface 304 of the substrate 302. The lightly doped region 314 with high sheet resistance is beneficial to reduce the recombination of carriers, whereas the heavily doped regions 312 with low sheet resistance can provide good ohmic contact. Thus, the substrate 302 has a grid pattern of heavily doped regions 312 which provide very low electrical resistance to provide a highly conductive path between the emitter region and the subsequently formed conductive contacts. The field regions (i.e., lightly doped regions 314) with high sheet resistance reduce the recombination of carriers and absorbs minimal light so that an increased amount of light is transmitted to the p-n junction 323 for conversion into electrical current. The pattern of the formed heavily doped regions 312 is configured to match the patterned metal contact structure, such as the conductive contacts 14 as discussed previously in conjunction with FIGS. 1A and 1B.

At step 416 shown in FIG. 4, after the single step diffusion process is finished, the substrate 302 may be gradually cooled to a desired temperature in the thermal processing chamber 240, as shown in FIGS. 2 and 4. The temperature of the substrate 302 may be ramped down at ramp-down rate between about 5° C./sec. and about 350° C./sec., for example about 150° C./sec., from the diffusion temperature of about 850° C. to a desired temperature of about 700° C. or less, such as about room temperature.

At step 418 shown in FIG. 4, an optional cleaning process may be performed on the substrate 302 in a second cleaning chamber 250 (FIG. 2) after the processes performed in step 416 are completed to remove any undesirable residues or oxides, such as phosphosilicate glass oxide formed during the diffusion step, from the substrate 302. The clean process may be performed in a similar fashion discussed above with respect to step 402. The clean process may be performed on the substrate 302 between about 5 seconds and about 600 seconds, such as about 30 seconds to about 240 seconds.

At step 420 shown in FIG. 4, an antireflection layer 316 is formed on the front surface 304 of the substrate 302 in a deposition chamber 260 (FIG. 2), as shown in FIG. 3F. The antireflection layer 316 may also include a transparent conductive oxide (TCO) layer (not shown). In one example, the antireflection layer 316 may be a thin passivation/antireflection layer, such as silicon oxide or silicon nitride. In certain embodiments where a heterojunction type solar cell is desired, the passivation/antireflection layer may include a thin (20-100 Å) intrinsic amorphous silicon (i-a-Si:H) layer followed by an ARC layer (e.g., silicon nitride), which can be deposited in the deposition chamber 260 using a physical vapor deposition (PVD) process or a chemical vapor deposition (CVD) process.

At step 422 shown in FIG. 4, portions of the antireflection layer 316 may be optionally etched, as shown in FIG. 3G, to expose regions 324 of the heavily doped regions 312 so that subsequently deposited conductive contacts can be placed in intimate contact with the exposed heavily doped regions 312. Thus, the etched pattern matches the pattern used to form the heavily doped regions 312. Typical etching processes that may be used to pattern the antireflection layer 316 may include patterning and dry etching techniques, laser ablation techniques, patterning and wet etching techniques, or other suitable processes. Alternatively, subsequently deposited conductive contacts 318 (in step 424) may be fired through the antireflection layer 316 without having to etch the antireflection layer 316.

At step 424 shown in FIG. 4, a conductive contact 318 is deposited in a pattern on the exposed heavily doped regions 312 on the substrate 302 in a deposition chamber 260 (FIG. 2), as shown in FIG. 3H. The conductive contact 318 may be between about 500 angstroms and about 50,000 angstroms (Å) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the conductive contact 318 is a metallic paste that contains silver (Ag) or tin (Sn) and is deposited in a pattern matching the pattern used to form the heavily doped regions 312 by first screen printing a metallic paste and heating the metallic paste to a desired temperature to sinter the paste. The screen printing process may be performed by a Softline™ tool available from Baccini S.p.A, a division of Applied materials, Inc. of Santa Clara, Calif. An example of the deposition chamber 260 is further disclosed in detail in U.S. patent application Ser. No. 12/418,912, entitled “NEXT GENERATION SCREEN PRINTING SYSTEM”, filed on Apr. 6, 2009, and U.S. Patent Publication No. 2009/0142880, entitled “SOLAR CELL CONTACT FORMATION PROCESS USING A PATTERNED ETCHANT MATERIAL,” filed on Nov. 19, 2008.

After step 424 shown in FIG. 4, heat is delivered to the conductive contact 318 to cause the metal in the conductive contact 318 to form an electrical connection to the heavily doped regions 312. The heating process may be performed in a heating oven within the deposition chamber 260. An example of the heating oven that may be used to perform the process steps in step 424 is further described in the commonly assigned and co-pending U.S. patent application Ser. No. 12/274,023, entitled “SOLAR CELL CONTACT FORMATION PROCESS USING A PATTERNED ETCHANT MATERIAL,” filed Oct. 24, 2008.

The present invention disclosed above relates to improved methods for making solar cells. Particularly, embodiments of the invention provide a single step diffusion process to be used in selective emitter solar cell fabrication at lower temperatures of about 850° C. or less. In various embodiments, the dopant paste is selectively applied (and optionally) dried on a textured front surface of the substrate. The substrate is then exposed to a desirable dopant containing vapor, e.g., phosphorus oxychloride (POCl₃), to deposit a doping layer on the front surface of the substrate. While the substrate being exposed to POCl₃ vapor, a portion of the dopant paste may also contribute to deposition of the doping layer via gas phase transport of phosphorus resulted from the dopant paste, thereby improving the doping efficiency of P atoms near the surface of the substrate. The substrate is then heated and annealed in an atmosphere comprising nitrogen and/or oxygen to a temperature that is sufficient to concurrently activate and cause the dopant atoms in the dopant paste and the doping layer to diffuse into the substrate a desired distance, forming heavily doped and lightly doped emitter regions. The heavily doped regions with low sheet resistance provide a highly conductive path between the emitter region and the subsequently formed conductive contacts. The lightly doped region with high resistance reduces the recombination of carriers and absorbs minimal light so that an increased amount of light is transmitted to the p-n junction for conversion into electrical current. The inventive single step diffusion process enables the manufacturing of solar cells with increased substrate throughput and reduced thermal budget, which also opens an opportunity for defect-rich substrates, e.g., multicrystalline (polycrystalline) and upgraded metallurgical grade (UMG) silicon substrates, thereby lowering the cost of making solar cells. Furthermore, the process according to the present invention also significantly improves the doping efficiency near the front surface of the solar cell compared to conventional two-step diffusion process.

While the foregoing is directed to embodiments of the present invention, other and further embodiments of the invention may be devised without departing from the basic scope thereof, and the scope thereof is determined by the claims that follow.

What is claimed is:

1. A method of forming a solar cell, comprising:
selectively applying a dopant material layer onto a surface of a substrate, the dopant material layer having opposite conductivity type from the substrate;
ramping up the temperature of the substrate in an oxygen-rich environment to diffuse the dopant material layer into the surface of the substrate;
exposing the substrate to a dopant containing vapor to deposit a doping layer on the surface of the substrate, the doping layer having opposite conductivity type from the substrate; and
heating the substrate to a temperature sufficient to cause dopant atoms in the dopant material and dopant atoms in the dopant layer to diffuse into the surface a desired distance.

2. The method of claim 1, wherein ramping up the temperature of the substrate comprises raising the temperature of the substrate to a temperature in a range between about 800° C. and about 850° C. at a ramp-up rate of about 5° C./second to about 150° C./second.

3. The method of claim 1, wherein heating the substrate is performed at a temperature range of about 800° C. and about 850° C.

4. A method of forming a solar cell, comprising:
texturing a surface of a substrate;
selectively applying a dopant material layer onto the textured surface of the substrate, the dopant material layer having opposite conductivity type from the substrate;
exposing the substrate to a dopant containing vapor to deposit a doping layer on the textured surface, the doping layer having opposite conductivity type from the substrate; and
heating the substrate to a temperature sufficient to cause dopant atoms in the dopant material and dopant atoms in the dopant layer to diffuse into the textured surface a desired distance.

5. The method of claim 4, further comprising:
prior to the exposing the substrate to the dopant containing vapor, ramping up the temperature of the substrate to a predetermined temperature to diffuse doping atoms of the dopant material into the textured surface of the substrate.

6. The method of claim 5, wherein ramping up the temperature of the substrate comprises raising the temperature of the substrate to a temperature in a range between about 800° C. and about 850° C. at a ramp-up rate of about 5° C./second to about 350° C./second.

7. The method of claim 5, wherein ramping up the temperature of the substrate is performed in an atmosphere comprising oxygen (O₂).

8. The method of claim 4, wherein the dopant material layer and the dopant containing vapor comprise phosphorus oxychloride (POCl₃).

9. The method of claim 8, wherein exposing the substrate to the dopant containing vapor is performed in an atmosphere comprising nitrogen (N₂) and/or oxygen (O₂).

10. The method of claim 4, wherein a portion of the dopant material layer is vaporized to lightly dope the textured surface of the substrate during exposing the substrate to the dopant containing vapor.

11. The method of claim 4, wherein heating the substrate is performed at a temperature range of about 800° C. and about 850° C. in an atmosphere comprising nitrogen (N₂) and/or oxygen (O₂).

12. The method of claim 4, wherein heating the substrate is performed first in an atmosphere containing pure nitrogen and then in an atmosphere containing pure oxygen.

13. A method of forming a solar cell, comprising:
selectively applying a dopant material layer onto a surface of a substrate, the dopant material layer having opposite conductivity type from the substrate;
exposing the substrate to a dopant containing vapor to deposit a doping layer on the surface, the doping layer having opposite conductivity type from the substrate; and
heating the substrate to a temperature sufficient to diffuse dopant atoms in the dopant material into the substrate to create a pattern of heavily doped regions and dopant atoms in the dopant layer into the surface to create lightly doped field regions, wherein the lightly doped regions are formed in between the heavily doped regions.

14. The method of claim 13, wherein exposing the substrate to the dopant containing vapor is performed in an atmosphere comprising nitrogen (N₂), oxygen (O₂), and a n-type dopant from the dopant containing vapor.

15. The method of claim 13, wherein a portion of the dopant material layer is vaporized to lightly dope the surface of the substrate during exposing the substrate to the dopant containing vapor.

16. The method of claim 13, wherein heating the substrate is performed in an atmosphere comprising nitrogen (N₂) and/or oxygen (O₂).

17. The method of claim 13, wherein heating the substrate is performed first in an atmosphere containing pure nitrogen and then in an atmosphere containing pure oxygen.

18. The method of claim 13, wherein the pattern of heavily doped regions has a sheet resistance (Rs) between about 20 Ω/□ and about 70 Ω/□ and the lightly doped field region has a sheet resistance (Rs) between about 80 Ω/□ and about 120 Ω/□.

19. The method of claim 13, further comprising:
prior to the exposing the substrate to the dopant containing vapor, ramping up the temperature of the substrate to a temperature range between about 800° C. and about 850° C.

20. The method of claim 13, wherein the substrate comprises monocrystalline silicon substrates, multicrystalline silicon substrates, upgraded metallurgical grade (UMG) crystalline silicon substrates, or substrates prepared by emitter wrap through (EWT), metallization wrap around (MWA), or metallization wrap through (MWT) approaches.
